(19) United States
(12) Patent Application Publication
(10) Pub. No.: US 2010/0032010 A1
(43) Pub. Date: Feb. 11, 2010

(54) METHOD TO MITIGATE SHUNT FORMATION IN A PHOTOVOLTAIC CELL COMPRISING A THIN LAMINA

(75) Inventors: S. Brad Herner, San Jose, CA (US); Christopher J. Petti, Mountain View, CA (US)

Correspondence Address: THE MUELLER LAW OFFICE, P.C., 12951 Harwick Lane, San Diego, CA, 92130, US

(73) Assignee: TWIN CREEKS TECHNOLOGIES, INC., San Jose, CA (US)

(21) Appl. No.: 12/189,156

(22) Filed: Aug. 10, 2008

(51) Int. Cl. H01L 31/00

(52) U.S. Cl. 136/256

(57) ABSTRACT

A photovoltaic cell can be formed from a thin semiconductor lamina cleaved from a substantially crystalline wafer. Shunts may inadvertently be formed through such a lamina, compromising device performance. By physically severing the lamina into a plurality of segments, the segments of the lamina preferably electrically connected in series, loss of efficiency due to shunt formation may be substantially reduced. In some embodiments, adjacent laminae are connected in series into strings, and the strings are connected in parallel to compensate for the reduction in current caused by severing the lamina into segments.

### RELATED APPLICATIONS

This application is related to Hilali et al., U.S. patent application Ser. No. ______, “Photovoltaic Cell Comprising a Thin Lamina Having a Rear Junction and Method of Making,” (attorney docket number TCA-007); and to Hilali et al., U.S. patent application Ser. No. ______, “Photovoltaic Cell Comprising a Thin Lamina Having Low Base Resistivity and Method of Making,” (attorney docket number TCA-001-1), both filed on even date herewith and owned by the assignee of the present application, and both hereby incorporated by reference.

This application is also related to Herner et al., U.S. patent application Ser. No. ______, “A Photovoltaic Module Comprising Thin Laminae Configured to Mitigate Efficiency Loss Due to Shunt Formation,” (attorney docket number TCA-006.z), filed on even date herewith, owned by the assignee of the present application, and hereby incorporated by reference.

### BACKGROUND OF THE INVENTION

The invention relates to a method to mitigate the loss of efficiency due to unintentional formation of shunts in a photovoltaic cell.

During fabrication of a photovoltaic cell, defects may cause an alternate current path, called a shunt, to form through the cell. The current path through this shunt is likely to be opposite to the photocurrent, and may seriously degrade the performance of the cell. The likelihood of shunt formation may increase with some fabrication techniques, and with thinner cells.

There is a need, therefore, for a method to mitigate the loss of efficiency caused by accidental formation of shunts.

### SUMMARY OF THE PREFERRED EMBODIMENTS

The present invention is defined by the following claims, and nothing in this section should be taken as a limitation on those claims. In general, the invention is directed to a method to mitigate the degradation of performance caused by accidental formation of a shunt or shunts in a photovoltaic cell.

A first aspect of the invention provides for a method to form a photovoltaic module, the method comprising: forming a substantially crystalline semiconductor lamina affixed to a receiver element; and severing the affixed semiconductor lamina into a plurality of segments, each segment remaining affixed to the receiver element, wherein each segment is a portion of a photovoltaic cell, and wherein the segments of the plurality are electrically connected in series.

Another aspect of the invention provides for a photovoltaic module comprising: a substantially crystalline semiconductor lamina, the semiconductor lamina severed into at least two physically separate segments, each segment of the semiconductor lamina permanently affixed to the same receiver element and remaining in its original orientation before severing, wherein the semiconductor lamina has a width measured parallel to the receiver element no more than about 300 mm, wherein each segment comprises at least a portion of a photovoltaic cell, and wherein the at least two physically separate segments are electrically connected in series.

An embodiment of the invention provides for a method for forming a photovoltaic module, the method comprising: defining a cleave plane in a first semiconductor donor wafer; affixing the first donor wafer to a first receiver element; cleaving a first semiconductor lamina from the first donor wafer along the cleave plane, wherein the first donor wafer remains affixed to the first receiver element; and severing the first semiconductor lamina into a first plurality of segments, wherein each segment remains affixed to the first receiver element, and wherein, in the completed photovoltaic module, each segment is at least a portion of a photovoltaic cell. Each of the aspects and embodiments of the invention described herein can be used alone or in combination with one another. The preferred aspects and embodiments will now be described with reference to the attached drawings.

### BRIEF DESCRIPTION OF THE DRAWINGS

FIG. 1 is a cross-sectional view of a prior art photovoltaic cell.

FIGS. 2a-2d are cross-sectional views illustrating stages in formation of an embodiment of Sivaram et al., U.S. patent application Ser. No. 12/026530.

FIGS. 3a-3c are cross-sectional views illustrating imperfect bonding of a donor wafer and a receiver and resulting shunt formation.

FIG. 4a is a plan view of a lamina severed into a plurality of segments according to an embodiment of the present invention. FIG. 4b is a plan view of a severed lamina having a shunt in one segment.

FIG. 5 is a circuit diagram showing photovoltaic cells connected in series in a prior art photovoltaic module.

FIG. 6a is a plan view of wherein laminae which have been severed into segments are connected in series in strings, then the strings connected in parallel, according to an embodiment of the present invention. FIG. 6b is a circuit diagram illustrating the laminae of FIG. 6a.

FIG. 7 is a plan view of a photovoltaic module including a plurality of laminae according to an embodiment of the present invention.

FIGS. 8a-8f are cross-sectional views showing stages in formation of a lamina severed into multiple segments according to an embodiment of the present invention.

FIGS. 9a and 9b are cross-sectional views showing stages in formation of a lamina severed into multiple segments according to another embodiment of the present invention.

### DETAILED DESCRIPTION OF THE PREFERRED EMBODIMENTS

A conventional prior art photovoltaic cell includes a p-n diode; an example is shown in FIG. 1. A depletion zone forms at the p-n junction, creating an electric field. Incident photons will knock electrons from the conduction band to the valence band, creating free electron-hole pairs. Within the electric field at the p-n junction, electrons tend to migrate toward the n region of the diode, while holes migrate toward the p region, resulting in current. This current can be called the photocurrent. Typically the dopant concentration of one region will be higher than that of the other, so the junction is either a p+/n− junction (as shown in FIG. 1) or a p−/n+ junction. The more lightly doped region is known as the base of the photovoltaic cell, while the more heavily doped region is known as the emitter. Most carriers are generated within the base, and it is typically the thickest portion of the cell. The base and emitter together form the active region of the cell.

Conventional photovoltaic cells are formed from monocrystalline, polycrystalline, or multicrystalline silicon. A monocrystalline silicon wafer, of course, is formed of a single silicon crystal, while the term multicrystalline typically refers to semiconductor material having crystals that are on the order of a millimeter in size. Polycrystalline semiconductor material has smaller grains, on the order of a thousand angstroms. Monocrystalline, multicrystalline, and polycrystalline material is typically entirely or almost entirely crystalline, with no or almost no amorphous matrix. For example, non-deposited semiconductor material is at least 80 percent crystalline.

Photovoltaic cells fabricated from substantially crystalline material are conventionally formed of wafers sliced from a silicon ingot. Current technology does not allow wafers of less than about 150 microns thick to be fabricated into cells economically, and at this thickness a substantial amount of silicon is wasted in kerf, or cutting loss. Silicon solar cells need not be this thick to be effective or commercially useful. A large portion of the cost of conventional solar cells is the cost of silicon feedstock, so decreasing the thickness of a photovoltaic cell may reduce cost.

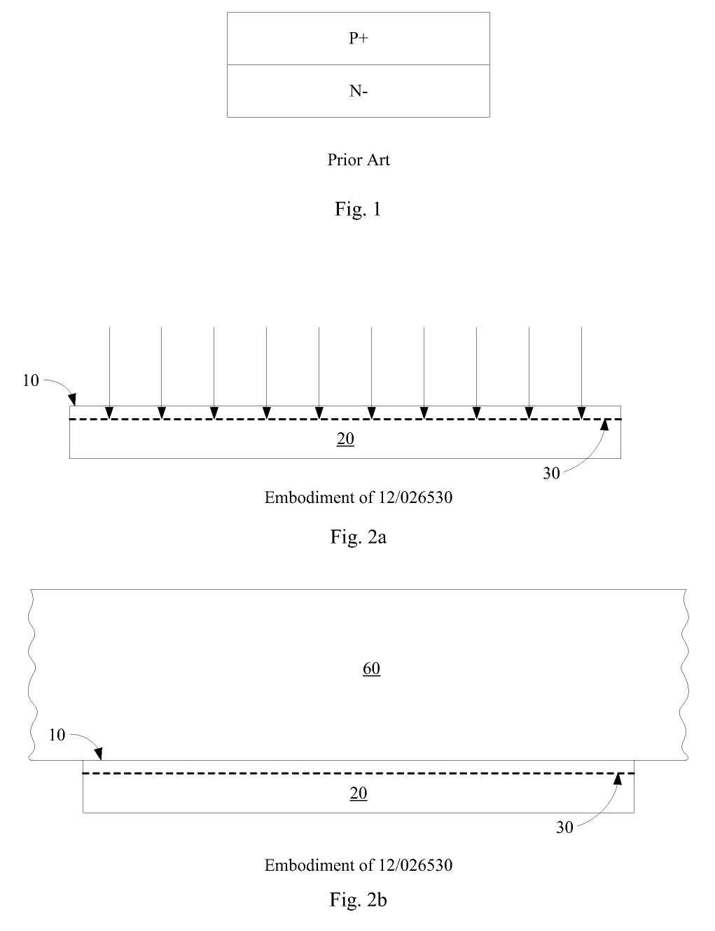

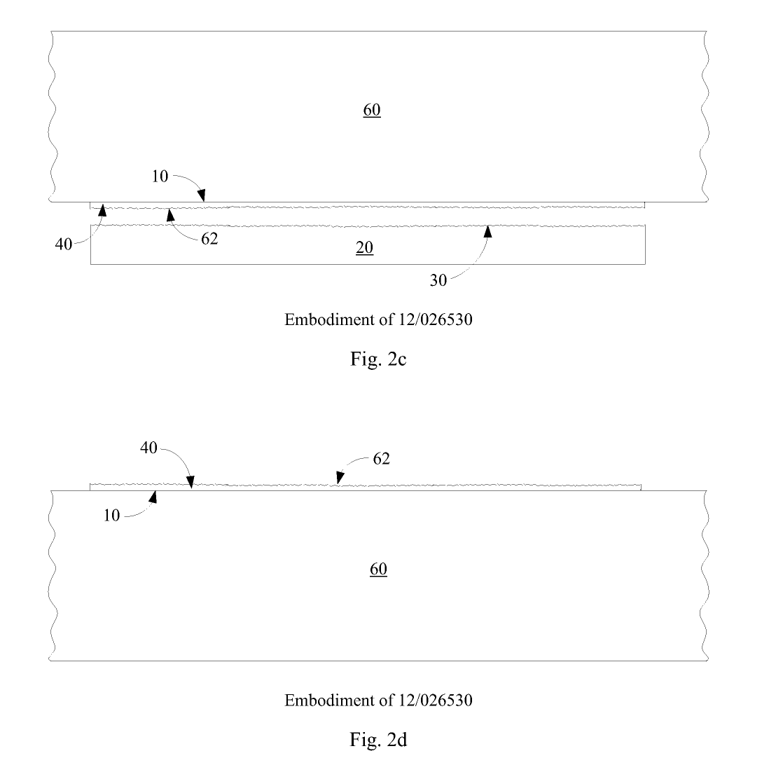

Sivaram et al., U.S. patent application Ser. No. 12/026530, “Method to Form a Photovoltaic Cell Comprising a Thin Lamina,” filed Feb. 5, 2008, owned by the assignee of the present application and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted with one or more species of gas ions, for example hydrogen or helium ions. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 50 microns thick, in some embodiments between about 1 and about 10 microns thick, though any thickness within the named range is possible. FIG. 2d shows the structure inverted, with receiver 60 at the bottom, as during operation in some embodiments.

Using the methods of Sivaram et al., photovoltaic cells are formed of thinner semiconductor laminae without wasting silicon through kerf loss or by formation of an unnecessarily thick wafer, thus reducing cost. The same donor wafer can be reused to form multiple laminae, further reducing cost, and may be resold after exfoliation of multiple laminae for some other use. The cost of the hydrogen or helium implant may be kept low by methods described in Parrill et al., U.S. patent application Ser. No. 12/122,108, “Ion Implanter for Photovoltaic Cell Fabrication,” owned by the assignee of the present application, filed May 16, 2008, and hereby incorporated by reference.

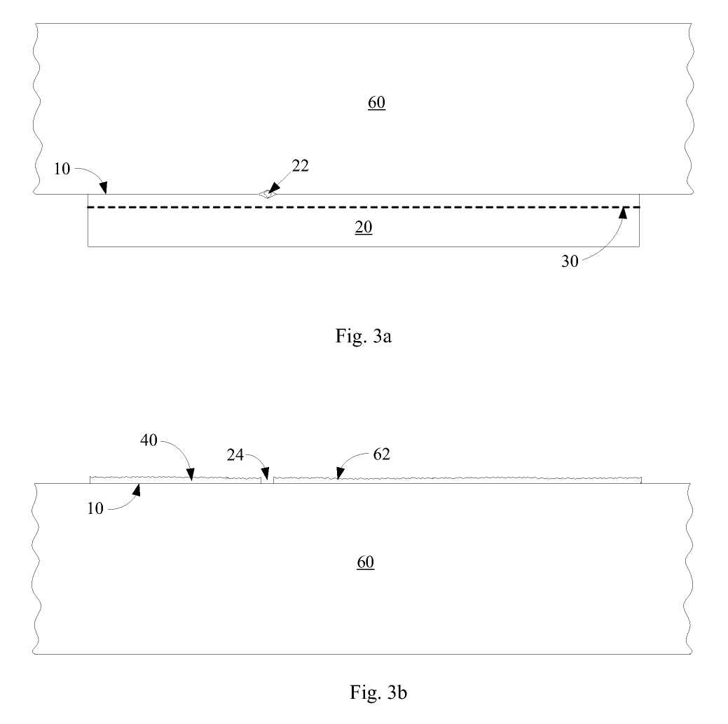

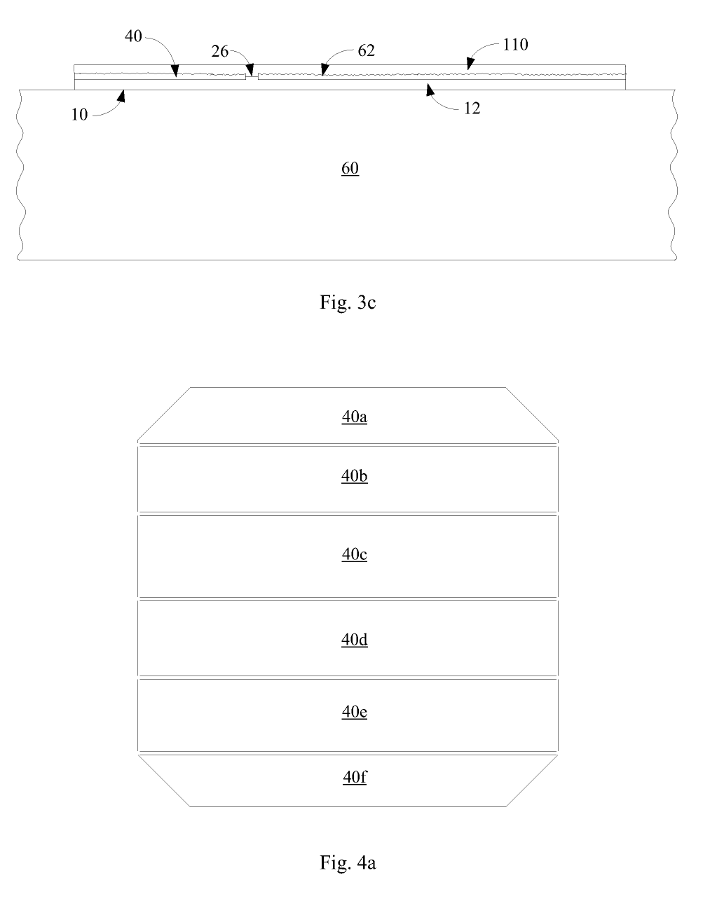

Referring to FIG. 3a, during fabrication of a semiconductor lamina as described by Sivaram et al., some contamination, for example particle 22, may be present between wafer 20 and receiver element 60, causing a small localized flaw in bonding of the two surfaces. At this point of imperfect bonding, as shown in FIG. 3b, after exfoliation there may be a void 24 in lamina 40. Several embodiments are described in Sivaram et al.; and in Herner, U.S. patent application Ser. No. 12/057,265, “Method to Form a Photovoltaic Cell Comprising a Thin Lamina Bonded to a Discrete Receiver Element,” filed Mar. 27, 2008, owned by the assignee of the present application and hereby incorporated by reference. In many of these embodiments, conductive materials are formed at opposite surfaces of lamina 40. For example, as shown in FIG. 3c, a metal 12 may be formed at first surface 10, while a transparent conductive oxide (TCO) 110 is formed at second surface 62. As can be seen, TCO 110 directly contacts metal 12 through the void, forming a shunt 26. Depending on its size, this shunt may drastically compromise device performance. Note the size of shunt 26 has been exaggerated for visibility.

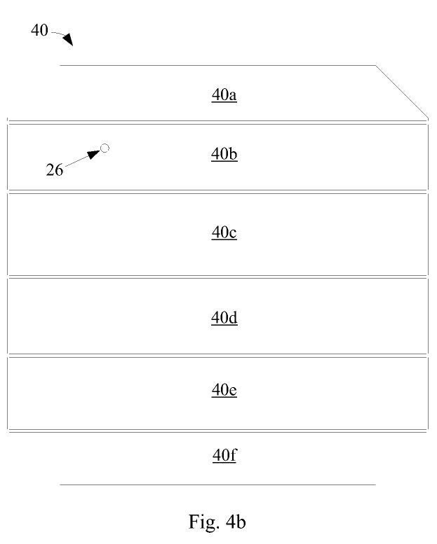

Referring to FIG. 4a, in the present invention, lamina 40 is physically severed into several segments 40a, 40b, 40c, etc., which may be connected in series, with the n-region of one segment connected to the p-region of the next. In practice the number of segments may be substantially greater than six, but a smaller number is shown for readability. Within the area of each segment 40a, 40b, 40c, etc. is a diode. In some embodiments, as in Sivaram et al. or Herner, portions of the diode, for example the emitter, may be included in an additional layer above or below the lamina itself. If, as shown in FIG. 4b, a shunt 26 forms in one of the segments 40b, shunt 26 compromises efficiency in segment 40b only, but segments 40a, 40c, etc., are not affected. Lamina 40 is most frequently formed from a conventional silicon wafer, which may be any standard or nonstandard size. In most embodiments, the segments are formed as parallel stripes, as shown in FIG. 4b, though they may be any shape. Lamina 40 may be severed into any number of stripes, for example between two and eighty, for example between twelve and sixty.

Summarizing, a photovoltaic module can be formed by forming a substantially crystalline semiconductor lamina affixed to a receiver element; and severing the affixed semiconductor lamina into a plurality of segments, each segment remaining affixed to the receiver element, wherein each segment is a portion of a photovoltaic cell, and wherein the segments of the plurality are electrically connected in series. In general, before the severing step, the semiconductor lamina has a width, measured parallel to the receiver element, no more than about 300 mm. Its thickness, measure perpendicular to the receiver element, is as described, for example between about 0.1 and about 80 microns. The severing step may be achieved by scribing the semiconductor lamina with a laser.

This method is one way to form a substantially crystalline semiconductor lamina, the semiconductor lamina severed into at least two physically separate segments, each segment of the semiconductor lamina permanently affixed to the same receiver element and remaining in its original orientation before severing, wherein the semiconductor lamina has a width measured parallel to the receiver element no more than about 300 mm, wherein each segment comprises at least a portion of a photovoltaic cell, and wherein the at least two physically separate segments are electrically connected in series.

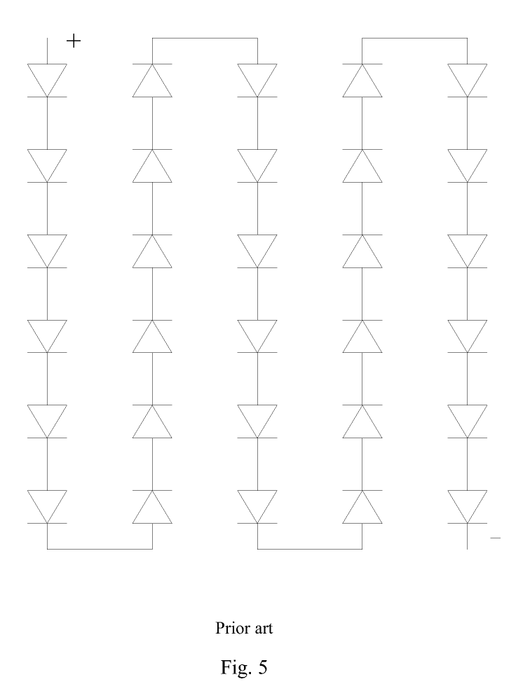

Lamina 40, which has been severed into multiple smaller segments which are connected in series, produces essentially the same power as an unsevered lamina of the same size, but, due to the smaller sizes of the segments, the total voltage appearing across this series assemblage is higher and current is lower. For example, suppose the voltage supplied by an unsevered lamina is V, and the current is I. If the lamina is divided into N segments connected in series, the voltage supplied by this total assemblage would be N*V, and the current supplied would be I/N. In general it is most convenient if current and voltage remain within a conventional range. In a conventional photovoltaic module consisting of unsevered wafer-sized crystalline photovoltaic cells, all of the photovoltaic cells are connected in series, as shown in the circuit diagram of FIG. 5. In embodiments of the present invention, a different electrical arrangement may be adopted to maintain conventional current and voltage ranges.

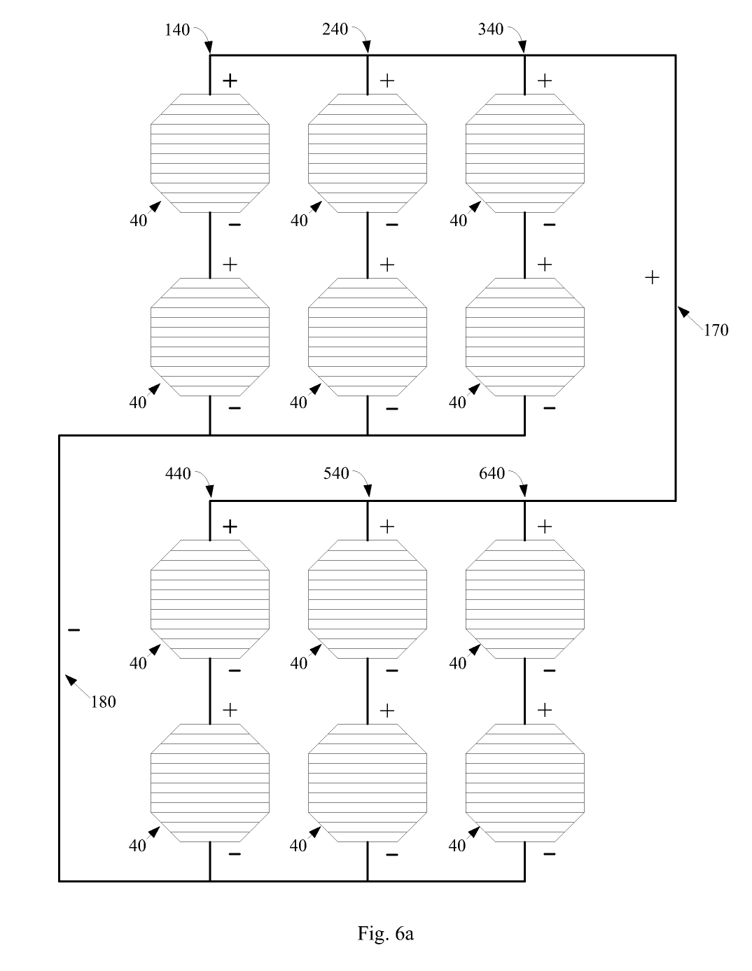

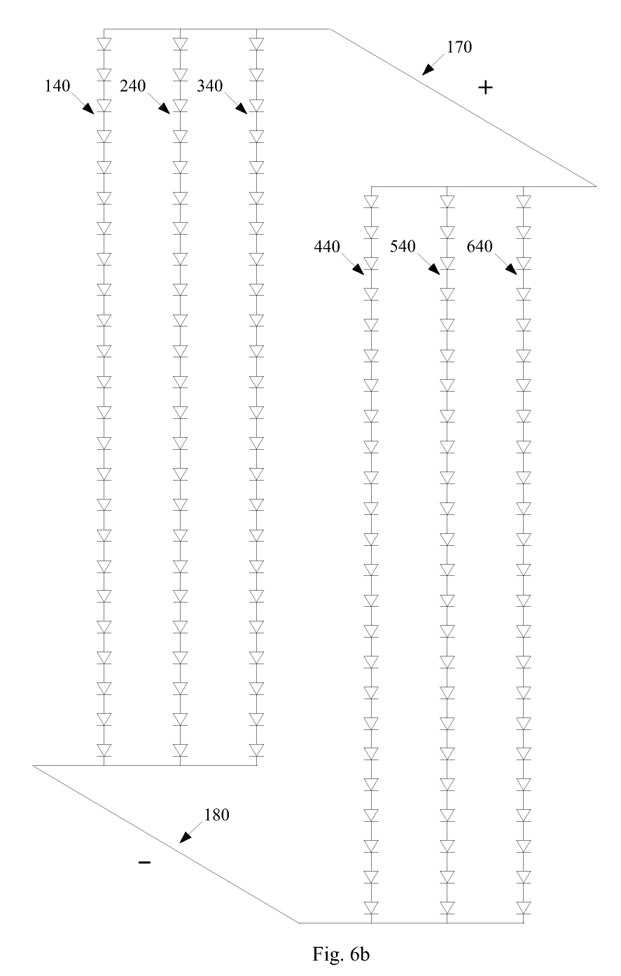

Currents and voltages may be kept in conventional ranges by forming strings of a small number of laminae connected electrically in series, the segments within each lamina in turn connected in series. The strings are then connected in parallel. For example, turning to FIG. 6a a first string 140 includes two laminae 40, the laminae connected in series. A second string 240 similarly includes two laminae 40 connected in series, as does a third string 340, fourth string 440, fifth string 540, and sixth string 640. Strings 140 through 640 are then connected in parallel, positive ends connected to the positive terminal 170 of the module, and negative ends to the negative terminal 180. In this example, each lamina 40 has been severed into twelve segments, the segments connected in series. This module includes six strings; an actual module may include many more.

FIG. 6b is a circuit diagram illustrating the connection of the segments within and between the laminae in FIG. 6a. If a shunt forms in one segment, that segment is compromised and generates little or no current. The remaining segments in that lamina, however, are unaffected.

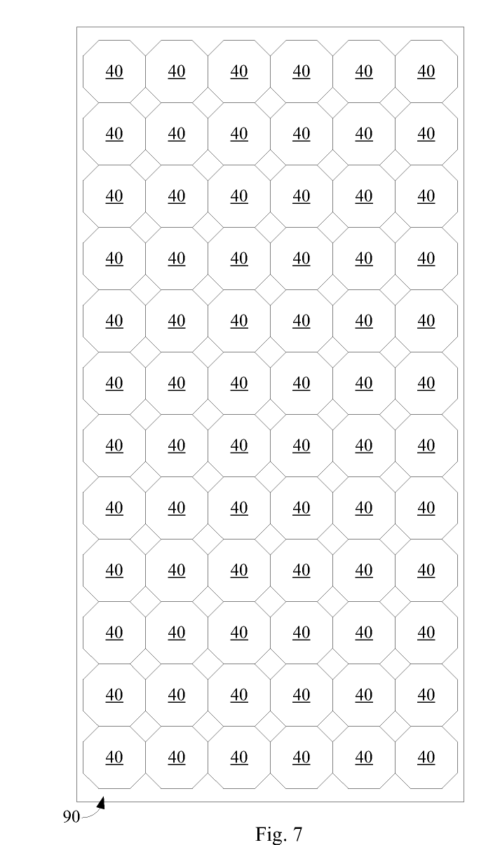

FIG. 7 shows many laminae 40 affixed to a single substrate 90. The earlier incorporated Herner application describes that each lamina 40 may be affixed to a receiver element (not shown), which has a width no more than about 50 percent more than that of the lamina 40, and is preferably about the same as the width of lamina 40. After fabrication of a plurality of photovoltaic assemblies, each comprising a lamina 40 and a receiver element, these photovoltaic assemblies can be tested and sorted, and photovoltaic assemblies of similar efficiency can be assembled on a single substrate 90 to form a photovoltaic module.

FIG. 7 shows an exemplary photovoltaic module formed according to an embodiment of the present invention. Seventy-two laminae 40, each of which has been affixed to a receiver element, then physically severed into two or more segments according to the present invention, have then been affixed to substrate 90 to form a photovoltaic module. The laminae are arranged in twelve rows each having six laminae. As will be clear to those skilled in the art, this is just one example provided for purposes of illustration, and many other arrangements may be preferred. In this example, each lamina 40 may be severed into thirty-six segments. Thirty-six strings are formed, each including two laminae connected in series; thus each string includes 72 segments connected in series.

The operating voltage of the photovoltaic module will be reduced by an amount related to the string having the most defects. If one string has shunts in five of its segments, for example, the module voltage (and thus power) will be reduced by a factor of approximately (72−5)/72=0.93. If desired, this one string could be disconnected. In this case, the operating voltage of the module is reduced by the next-worse string, which may have only two defects, or (70/72)=0.97, and the current is reduced by one string (35/36=0.97); thus the power is reduced by 0.94, which is slightly better than if the string was not removed. Alternatively, laminae with more than a certain number of defects can be excluded prior to assembly.

The photovoltaic module thus formed includes a plurality of semiconductor laminae, each lamina physically severed into a plurality of segments, the segments of each lamina electrically connected in series, wherein a photovoltaic cell comprises each segment; and a plurality of strings, each string comprising two or more of the semiconductor laminae, the semiconductor laminae of each string electrically connected in series, wherein the strings are electrically connected in parallel. To summarize, such a structure can be formed by forming a plurality of photovoltaic assemblies, each comprising a semiconductor lamina affixed to a receiver element, each semiconductor lamina severed into at least two segments, the segments of each lamina connected in series; affixing the plurality of photovoltaic assemblies to a single substrate or superstrate; electrically connecting the laminae of at least some of the photovoltaic assemblies into strings; detecting at least one defective segment within one of the laminae; and electrically connecting at least some of the strings in parallel wherein a) no electrical connection is formed to the lamina that includes the defective segment or b) no electrical connection is formed to the string that includes the defective segment. The laminae within a string generally are electrically connected in series.

For clarity, several examples of fabrication of a lamina having thickness between 0.2 and 100 microns, where the lamina is severed into two or more segments to mitigate loss of efficiency due to shunt formation, will be provided. For completeness, many materials, conditions, and steps will be described. It will be understood, however, that many of these details can be modified, augmented, or omitted while the results fall within the scope of the invention. In these embodiments, it is described to cleave a semiconductor lamina by implanting gas ions and exfoliating the lamina. Other methods of cleaving a lamina from a semiconductor wafer could also be employed in these embodiments.

Example: Photovoltaic Cell with TCO Front Contact

The process begins with a donor body of an appropriate semiconductor material. An appropriate donor body may be a monocrystalline silicon wafer of any practical thickness, for example from about 300 to about 1000 microns thick. In alternative embodiments, the wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. The donor wafer is preferably at least 80 percent crystalline, and in general will be entirely crystalline. In general a donor wafer has an average crystal size of at least 1000 angstroms. In some embodiments the semiconductor lamina consists essentially of silicon. It may, for example, consist essentially of monocrystalline semiconductor material.

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with no unused gaps between them. The diameter or width of the wafer may be any standard or custom size. For simplicity this discussion will describe the use of a monocrystalline silicon wafer as the semiconductor donor body, but it will be understood that donor bodies of other types and materials can be used. Octagonal-shaped wafers will be pictured in the examples provided, but wafers of any shape, for example square or circular, can be used.

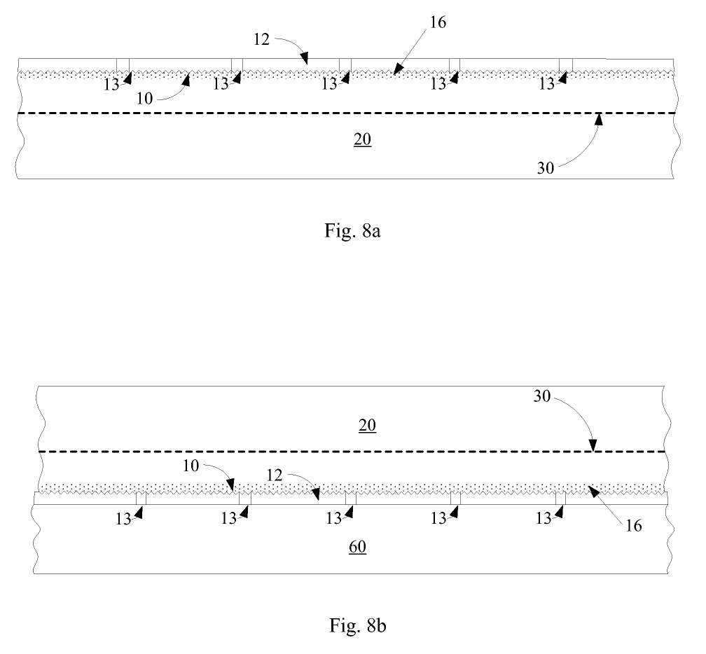

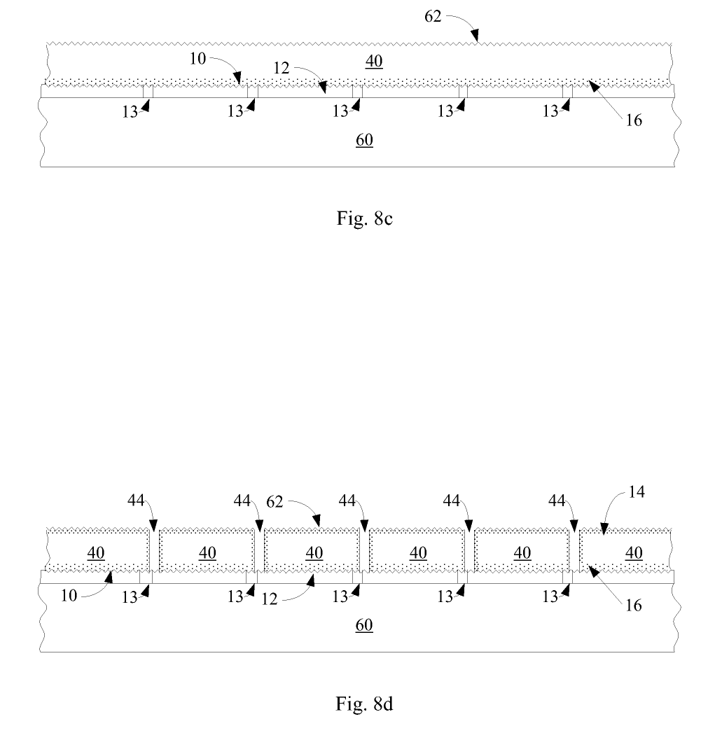

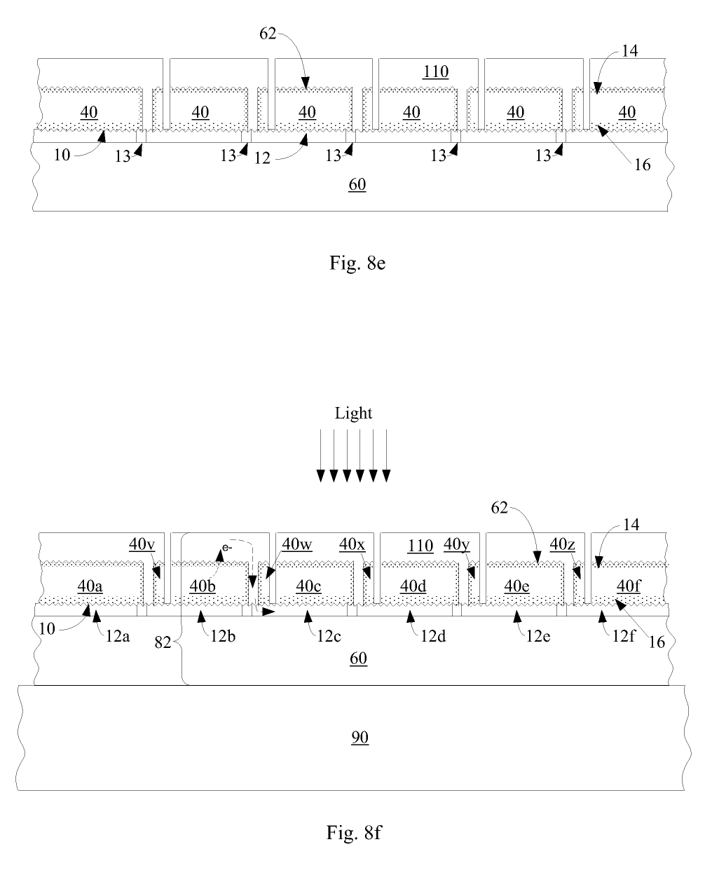

Referring to FIG. 8a wafer 20 is formed of monocrystalline silicon which is preferably lightly doped to a first conductivity type. The present example will describe a relatively lightly n-doped wafer 20 but it will be understood that in this and other embodiments the dopant types can be reversed. Dopant concentration may be between about 1×10¹⁴ and 3×10¹⁸ atoms/cm³; for example between about 3×10¹⁵ and 1×10¹⁸ atoms/cm³; for example about 2×10¹⁷ atoms/cm³. Desirable resistivity for n-type silicon may be, for example, between about 44 and about 0.01 ohm-cm, preferably about 1.6 to about 0.02 ohm-cm, for example about 0.06 ohm-cm. For p-type silicon, desirable resistivity may be between about 133 and about 0.02 ohm-cm, preferably between about 4.6 and about 0.04 ohm-cm, for example about 0.12 ohm-cm.

First surface 10 is optionally treated to produce surface roughness, for example, to produce a Lambertian surface. The ultimate thickness of the lamina limits the achievable roughness. In conventional silicon wafers for photovoltaic cells, surface roughness, measured peak-to-valley, is on the order of a micron. In embodiments of the present invention, the thickness of the lamina may be between about 0.2 and about 100 microns. Preferred thicknesses include between about 1 and about 80 microns; for example, between about 1 and about 20 microns or between about 2 and about 20 microns. Practically, any thickness in the range between about 0.2 and about 100 microns is achieveable; advantageous thicknesses may be between about 1 and about 1.5, 2, 3, 5, 8, 10, 20, or 50 microns.

If the final thickness is about 2 microns, clearly surface roughness cannot be on the order of microns. For all thicknesses, a lower limit of surface roughness would be about 500 angstroms. An upper limit would be about a quarter of the film thickness. For a lamina 1 micron thick, surface roughness may be between about 600 angstroms and about 2500 angstroms. For a lamina having a thickness of about 10 microns, surface roughness will be less than about 25000 angstroms, for example between about 600 angstroms and 25000 angstroms. For a lamina having a thickness of about 20 microns, surface roughness may be between about 600 angstroms and 50000 angstroms.

Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001. Formation of surface roughness is described in further detail in Petti, U.S. patent application Ser. No. 12/130,241, “Asymmetric Surface Texturing For Use in a Photovoltaic Cell and Method of Making,” filed May 30, 2008, owned by the assignee of the present application and hereby incorporated by reference.

Next first surface 10 is doped, for example by diffusion doping. First surface 10 will be more heavily doped to the conductivity type opposite that of original wafer 20. In this instance, donor wafer 20 is n-type, so first surface 10 is doped with a p-type dopant, forming heavily doped p-type region 16. Doping may be performed with any conventional p-type donor gas, for example B₂H₆ or BCl₃. Doping concentration may be, for example, between about 1×10¹⁸ and 1×10²¹ atoms/cm³, for example about 1×10²⁰ atoms/cm³. In other embodiments, this diffusion doping step can be omitted.

Next ions, preferably hydrogen or a combination of hydrogen and helium, are implanted to define a cleave plane 30, as described earlier. Note that the plane of maximum distribution of implanted ions, and of implant damage, is conformal. Any irregularities at first surface 10 will be reproduced in cleave plane 30. Thus in some embodiments if first surface 10 is roughened, it may be preferred to roughen surface 10 after the implant step rather than before. Once the implant has been performed, exfoliation will occur once certain conditions, for example elevated temperature, are encountered. It is necessary, then, to keep processing temperature and duration below those which will initiate exfoliation until exfoliation is intended to take place.

Next conductive layer 12 is formed on first surface 10. In most embodiments, layer 12 is also reflective. Alternatives for such a layer, in this and other embodiments, include aluminum, titanium, chromium, molybdenum, tantalum, silver zirconium, vanadium, indium, cobalt, antimony, tungsten, rhodium, or alloys thereof. In some embodiments, it may be preferred to deposit a thin layer 12 of titanium onto first surface 10, though conductive layer 12 may be formed by any appropriate method.

Next layer 12 is separated into two or more discrete sections, for example by laser scribing. In this example layer 12 is separated into six discrete sections. Another number of segments may be chosen, for example at least four or at least ten. In most embodiments there will be more than six segments; the number shown is limited for readability. The scribe lines can be any desired width, in most embodiments at least 10 microns, for example between 10 and 100 microns. In some examples the scribe lines are about 40 microns wide. Stripes of an insulating material 13 fill the scribe lines and provide electrical isolation between the sections of conductive layer 12. In one embodiment, silicon dioxide is deposited on layer 12, then a planarizing step, for example by chemical-mechanical polishing, removes the excess silicon dioxide, leaving stripes of insulating material 13 between sections of conductive layer 12 and producing a substantially planar surface.

Turning to FIG. 8b, the surface of layer 12 is cleaned of foreign particles, then affixed to receiver element 60. FIG. 8b shows the structure with receiver element 60 on the bottom. Receiver element 60 is preferably insulating, or has an insulating layer at the surface contacting conductive layer 12. In alternative embodiments, layer 12 may have been formed on receiver element 60, rather than on first surface 10 of donor wafer 20. As shown in FIG. 8c, lamina 40 can now be cleaved from donor wafer 20 at cleave plane 30 as described earlier. Lamina 40 remains affixed to receiver element 60 with conductive layer 12 disposed between them, as described in Herner et al., U.S. patent application Ser. No. 12/057274, “A Photovoltaic Assembly Including a Conductive Layer Between a Semiconductor Lamina and a Receiver Element,” filed Mar. 27, 2008, owned by the assignee of the present application and hereby incorporated by reference. Second surface 62 has been created by exfoliation. As has been described, some surface roughness is desirable to increase light trapping within lamina 40 and improve conversion efficiency of the photovoltaic cell. The exfoliation process itself creates some surface roughness at second surface 62. In some embodiments, this roughness may alone be sufficient. In other embodiments, surface roughness of second surface 62 may be modified or increased by some other known process, such as a wet or dry etch, or by the methods described by Petti, as may have been used to roughen first surface 10.

As show in FIG. 8d, next lamina 40 is severed into two or more segments; in this example, lamina 40 is severed into six segments. In most embodiments, there will be more than six segments, but fewer segments are pictured for readability. This severing may be performed in a variety of ways, for example by laser scribing. As in the previous laser scribing step, the wavelength of the laser is selected to be absorbed by the material to be scribed. For this step, a laser wavelength is chosen that is absorbed by crystalline silicon, and is absorbed much less or not at all by conductive layer 12 and insulating material 13. The width of gaps 44 in lamina 40 formed by scribing may be the same as in conductive layer 12, preferably less than about 100 microns, for example between 10 and 100 microns, for example about 40 microns. Gaps 44 in lamina 40 should be at about the same pitch as the scribe lines, now filled with stripes 13 of insulating material, in conductive layer 12. As will be seen in a later step gaps 44 will be filled with conductive material. As will be described in more detail, the width and orientation of each gap 44 relative to each stripe of insulating material 13 should be selected so that insulating stripes 13 and gaps 44 are substantially parallel, and the edge between an insulating stripe 13 and adjacent conductive section 12 falls within a gap 44.

Next the top of lamina 40 is heavily doped through second surface 62 to the same conductivity type as the original wafer 20, forming doped region 14. In this example, original wafer 20 was lightly n-doped, so doped region 14 will be n-type. This doping may be performed by any conventional means. In preferred embodiments this doping step is performed by diffusion doping using any appropriate donor gas that will provide an n-type dopant, for example, POCl₃. Note that diffusion doping will cause the walls of gaps 44 to be doped as well, as shown. This doping step should counter-dope portions of heavily doped p-type regions 16 at the sidewalls, as shown, such that the sidewalls are entirely n-doped. Care should be taken that the junction between p-regions 16 and n-regions 14 contacts insulating region 13 on the right sides of the lamina sections as shown in FIG. 8d, rather than a portion of conductive layer 12. As will be seen, the left sides of the laminate junctions will be isolated by the next laser step.

Diffusion doping is typically performed at relatively high temperature, for example between about 700 and about 900 degrees C., although lower temperature methods, such as plasma enhanced diffusion doping, can be performed instead.

Next, turning to FIG. 8e, TCO 110 is deposited on second surface 62, forming an electrical contact to n-doped region 14. Note that TCO 110 will also fill gaps 44 shown in FIG. 8d. Appropriate materials for TCO 110 include aluminum-doped zinc oxide, as well as indium tin oxide, tin oxide, titanium oxide, etc.; this layer may serve as both a top electrode and an antireflective layer and may be between about 500 and 10,000 angstroms thick, for example, about 5,000 angstroms thick. In alternative embodiments, an additional antireflective layer may be formed on top of TCO 110. After formation of TCO 110, a final laser scribing step is performed, severing both TCO 110 and lamina 40. As TCO 110 and lamina 40 are composed of different materials, this laser scribing will likely be performed in two stages using lasers of different wavelengths.

Referring to FIG. 8f, which shows completed photovoltaic assembly 82, in this example lamina 40 has been severed into six segments, 40a-40f. Each segment is at least a portion of a photovoltaic cell. When exposed to light, the flow of free electrons (e-, flow indicated by the dotted arrow) generated in lamina segment 40b will flow from segment 40b through TCO 110, then through a channel of TCO formed in prior scribed gap 44 (see FIG. 8d) to conductive section 12c, which connects to p-doped region 16 of segment 40c. Thus segments 40a-40f are electrically connected in series. There may be small isolated lamina remnants 40v-40z (for readability their width relative to segments 40a-40f is exaggerated in these figures), which have negligible electrical effect. If desired, the scribe lines in lamina 40 or in TCO 110 and lamina 40 can be made wider to remove lamina remnants 40v-40z entirely. The width of each of lamina remnants 40v-40z is most often on the order of 100 microns or less.

Light enters each segment 40a-40f at second surface 62, which is the front of the cell. Note that in this embodiment each segment is a p+/n− diode, with the junction between the body of lightly doped n-type lamina 40 and heavily doped region 16 at the back of the cell. In other embodiments, it may be preferred to form the junction between the body of the lamina and the heavily doped region at the front of the cell. This can be accomplished simply by starting with a p-doped lamina body rather than an n-doped.

As described earlier, a plurality of photovoltaic assemblies 82 can be affixed to a substrate 90 or superstrate, as in FIG. 7, forming a photovoltaic module. In this example, the emitter and base of the photovoltaic cell are included within each semiconductor lamina. Sivaram et al. and Herner include additional embodiments, any of which can be modified according to teachings of the present application. In some of these embodiments, the lamina may not comprise both the emitter and base of the photovoltaic cell. For example, in some embodiments, the lamina is all or a portion of the base of the cell, while an amorphous layer serves as the emitter.

Summarizing, the structure has been formed by defining a cleave plane in a first semiconductor donor wafer; affixing the first donor wafer to a first receiver element; cleaving a first semiconductor lamina from the first donor wafer along the cleave plane, wherein the first donor wafer remains affixed to the first receiver element; and severing the first semiconductor lamina into a first plurality of segments, wherein each segment remains affixed to the first receiver element, and wherein, in the completed photovoltaic module, each segment is at least a portion of a photovoltaic cell. In this example, the cleave plane was defined by implanting one or more species of gas ions into the semiconductor donor wafer. In the completed photovoltaic module, the segments of each lamina are electrically connected in series.

Example: Photovoltaic Cell with Front Surface Wiring

In the previous example, electrical contact was made to the front surface of the photovoltaic cell with a TCO. In alternative embodiments, metal wiring may be formed to make electrical contact to the front surface of the photovoltaic cell instead. An example of such a photovoltaic cell, comprising a lamina severed into a plurality of segments according to the present invention, will be provided.

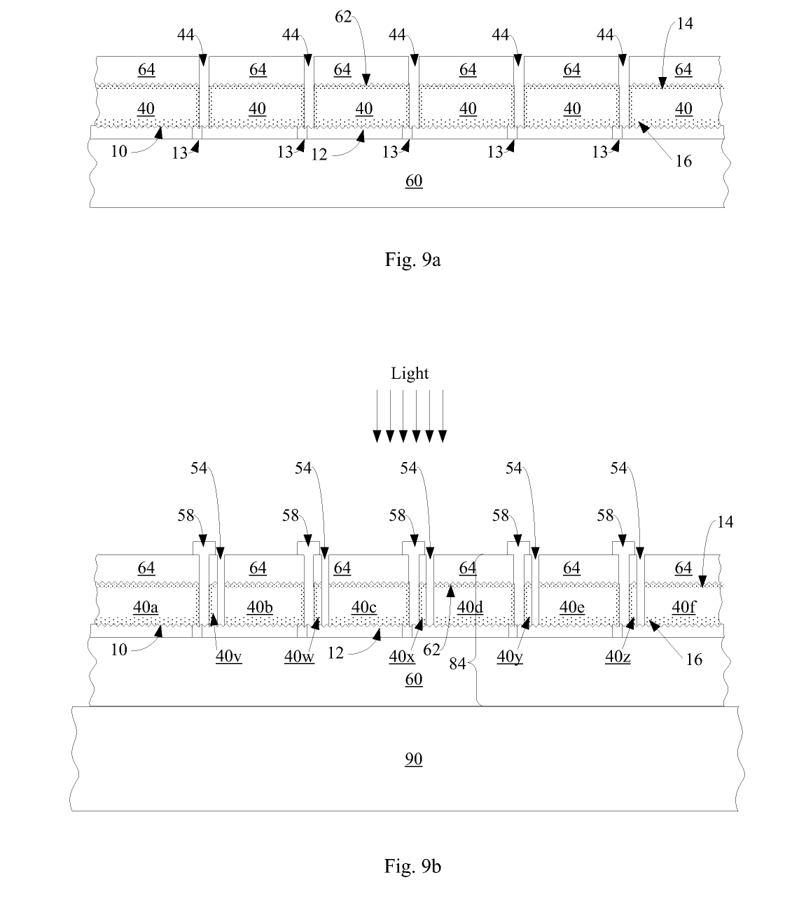

Referring to FIG. 9a fabrication begins as in the previous example. A first surface 10 of a lightly n-doped donor wafer (not shown), which may be textured, is doped to form p-doped region 16, then a cleave plane (not shown) is defined in the donor wafer, for example by implanting hydrogen and/or helium ions. Conductive layer 12 is formed on first surface 10, then layer 12 is divided, for example by laser scribing, into a plurality of sections, for example thirty-six sections. For readability, only six sections will be shown. The sections are separated by insulating stripes 13, formed as described earlier.

As in the prior example, first surface 10 of the donor wafer is affixed to receiver element 60 with conductive layer 12 disposed between them, then lamina 40 is cleaved from the donor wafer at the previously defined cleave plane, creating second surface 62, which may be textured. Lamina 40 is severed into segments, in this example into six segments. Gaps 44 are substantially parallel to insulating stripes 13. The orientation and width of gaps 44 relative to insulating stripes 13 may be as in the prior embodiment. A doping step, for example by diffusion doping, forms n-doped region 14 at second surface 62 and at the walls of gaps 44.

Antireflective layer 64 is preferably formed, for example by deposition or growth, on second surface 62. Incident light enters lamina 40 through second surface 62; thus this layer should be transparent. In some embodiments antireflective layer 64 is silicon nitride, which has a refractive index of about 1.5 to 3.0; its thickness would be, for example, between about 500 and 2000 angstroms, for example about 650 angstroms. Silicon nitride is substantially an insulating material.

An additional laser scribing step removes antireflective material 64 from gaps 44, reopening these gaps. Next, turning to FIG. 9b interconnects 58 are formed in gaps 44 (shown in FIG. 9a) by any suitable method.

Next a final laser scribing step forms gaps 54 through antireflective layer 64 and lamina 40, leaving isolated lamina remnants 40v-40z. As in the prior embodiment, when exposed to light, electrons will flow from segment 40b through n-doped region 14, then through interconnect 58b to the adjacent section of conductive layer 12. Thus segments 40a-40f are electrically connected in series. As in prior embodiments, the entire photovoltaic assembly 84, which comprises lamina 40 and receiver element 60, can be affixed, along with other photovoltaic assemblies, to a substrate 90 or superstrate, forming a photovoltaic module. As in the prior example, a small number of laminae, for example two or three, are connected in series to form strings, and the strings are then connected in parallel.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method to form a photovoltaic module, the method comprising:
forming a substantially crystalline semiconductor lamina affixed to a receiver element; and
severing the affixed semiconductor lamina into a plurality of segments, each segment remaining affixed to the receiver element, wherein each segment is a portion of a photovoltaic cell, and wherein the segments of the plurality are electrically connected in series.

2. The method of claim 1 wherein the semiconductor lamina has a thickness, measured perpendicular to the receiver element, between about 0.5 and 50 microns.

3. The method of claim 1 wherein, before the severing step, the semiconductor lamina has a width, measured parallel to the receiver element, less than about 300 mm.

4. The method of claim 1 wherein the semiconductor lamina has an average crystal size of at least 1000 angstroms.

5. The method of claim 1 wherein the semiconductor lamina is at least 80 percent crystalline.

6. The method of claim 1 wherein the semiconductor lamina consists essentially of silicon.

7. The method of claim 1 wherein the step of severing the semiconductor lamina into a plurality of segments comprises scribing the semiconductor lamina with a laser.

8. The method of claim 1 wherein the semiconductor lamina is severed into at least 4 segments.

9. The method of claim 8 wherein the semiconductor lamina is severed into at least 10 segments.

10. The method of claim 1 wherein the step of forming a substantially crystalline semiconductor lamina affixed to a receiver element comprises:
defining a cleave plane in a semiconductor donor wafer;
affixing the donor wafer to the receiver element at a first surface of the donor wafer; and
cleaving the semiconductor lamina from the semiconductor donor wafer along the cleave plane.

11. The method of claim 10 further comprising, before the affixing step, doping at least a portion of the first surface of the donor wafer.

12. A photovoltaic module comprising:
a substantially crystalline semiconductor lamina, the semiconductor lamina severed into at least two physically separate segments, each segment of the semiconductor lamina permanently affixed to the same receiver element and remaining in its original orientation before severing,
wherein the semiconductor lamina has a width measured parallel to the receiver element no more than about 300 mm,
wherein each segment comprises at least a portion of a photovoltaic cell, and wherein the at least two physically separate segments are electrically connected in series.

13. The photovoltaic module of claim 12 wherein the semiconductor lamina consists essentially of monocrystalline semiconductor material.

14. The photovoltaic module of claim 12 wherein the semiconductor lamina has a thickness, measured normal to the receiver element, of between about 0.2 and about 100 microns.

15. The photovoltaic module of claim 14 wherein the thickness of the semiconductor lamina is between about 0.5 and about 20 microns.

16. The photovoltaic module of claim 12 wherein the lamina is severed into at least 10 physically separate segments.

17. The photovoltaic module of claim 12 wherein the semiconductor lamina consists essentially of silicon.

18. A method for forming a photovoltaic module, the method comprising:
defining a cleave plane in a first semiconductor donor wafer;
affixing the first donor wafer to a first receiver element;
cleaving a first semiconductor lamina from the first donor wafer along the cleave plane, wherein the first donor wafer remains affixed to the first receiver element; and
severing the first semiconductor lamina into a first plurality of segments, wherein each segment remains affixed to the first receiver element, and wherein, in the completed photovoltaic module, each segment is at least a portion of a photovoltaic cell.

19. The method of claim 18 wherein the semiconductor lamina has a thickness between about 0.5 and about 20 microns.

20. The method of claim 18 wherein the semiconductor lamina is at least 80 percent crystalline.

21. The method of claim 20 wherein the semiconductor lamina is monocrystalline semiconductor material.

22. The method of claim 20 wherein the average crystal size of the semiconductor lamina is at least 1000 angstroms.

23. The method of claim 18 wherein the step of defining a cleave plane in a semiconductor donor wafer comprises implanting one or more species of gas ions into the semiconductor donor wafer.

24. The method of claim 18 wherein the step of severing the first semiconductor lamina into a plurality of first segments is performed by laser scribing.

25. The method of claim 18 wherein, in the completed photovoltaic module, the segments of the first plurality are electrically connected in series.
